(19) United States
(12) Patent Application Publication
(10) Pub. No.: US 2020/0152650 A1
(43) Pub. Date: May 14, 2020

(54) MEMORY DEVICE WITH A SPLIT STAIRCASE

(71) Applicant: Intel Corporation, Santa Clara, CA (US)

(72) Inventors: Deepak Thimmegowda, Fremont, CA (US); Owen Jungroth, Sonora, CA (US); Khaled Hasnat, San Jose, CA (US); David Meyaard, Boise, ID (US); Surendranath C. Eruvuru, Boise, ID (US)

(21) Appl. No.: 16/184,641

(22) Filed: Nov. 8, 2018

(51) Int. Cl. H01L 27/11556; G11C 5/06; H01L 27/11524; H01L 27/11519

(52) U.S. Cl. CPC H01L 27/11556; H01L 27/11519; H01L 27/11524; G11C 5/063

(57) ABSTRACT

Embodiments of the present disclosure are directed towards a memory device with a split staircase, in accordance with some embodiments. In one embodiment, the memory device includes one or more pillars disposed in a die, and a plurality of wordlines formed in a stack of multiple tiers and coupled with the one or more pillars. At least some of the wordlines are split across the tiers into at least first and second portions. Respective ends of at least some wordlines of at least one of the first or second portions, at a location of the split, are exposed to provide electrical coupling with other components of the device. Other embodiments may be described and/or claimed.

### FIELD

Embodiments of the present disclosure generally relate to the field of integrated circuits, and more particularly, to fabrication techniques for a non-volatile memory device.

### BACKGROUND

A typical flash memory device may comprise a memory array that includes a large number of non-volatile memory cells arranged in row and column fashion. In recent years, vertical memory, such as three-dimensional (3D) memory, has been developed in various forms, such as NAND, NOR, cross-point, or the like. A 3D flash memory array may include a plurality of memory cells stacked over one another. Each group of memory cells may share a plurality of access lines, known as wordlines and bitlines.

In NAND memory technology, particularly in 3D NAND memory technology, wordline connection disposition is an important architecture decision which affects die area, die performance and system metrics. 3D NAND word line connections are typically created by forming a staircase, e.g., by etching and trimming back the photoresist, to get access to each individual wordline. As the number of wordlines increases from generation to generation of memory devices, the amount of staircase trims and etches also increases. If the height of the individual memory blocks is kept the same, based on architectural limitations such as performance, reliability, and/or power, the amount of die area to route all these wordlines gets increasingly limited.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1-2 are example cross-section and perspective views of a memory device with a split staircase, in accordance with some embodiments.

FIG. 3 provides example views of some aspects of the memory device with a split staircase, in accordance with some embodiments.

FIG. 4 provides example views of some aspects of the memory device with a split staircase and with application of a chop mask, in accordance with some embodiments.

FIG. 5 is an example cross-section view of some aspects of the memory device with multiple split staircases, in accordance with some embodiments.

FIG. 6 is an example process flow diagram for providing a memory device with a split staircase, in accordance with some embodiments.

FIG. 7 is an example top view of some aspects of a memory device with a split staircase with application of a chop mask, in accordance with some embodiments.

FIG. 8 is an example top view of some aspects of a memory device with a split staircase with application of a chop mask, in accordance with some embodiments.

FIG. 9 is an example top view of some aspects of a memory device with multiple split staircases with application of chop masks, in accordance with some embodiments.

FIG. 10 is an example top view of some aspects of a memory device with multiple split staircases, in accordance with some embodiments.

FIG. 11 is an example top view of some aspects of a memory device with multiple split staircases, in accordance with some embodiments.

FIG. 12 schematically illustrates an example computing device including a memory device with a split staircase, in accordance with some embodiments.

### DETAILED DESCRIPTION

Embodiments of the present disclosure describe techniques and configurations for a memory device with a split staircase, in accordance with some embodiments. In embodiments, the memory device includes one or more pillars disposed in a die, and a plurality of wordlines formed in a stack of multiple tiers and coupled with the one or more pillars. At least some of the wordlines are split across the tiers into at least first and second portions. Respective ends of at least some wordlines of at least one of the first or second portions, at a location of the split, are exposed to provide electrical coupling with other components of the device.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

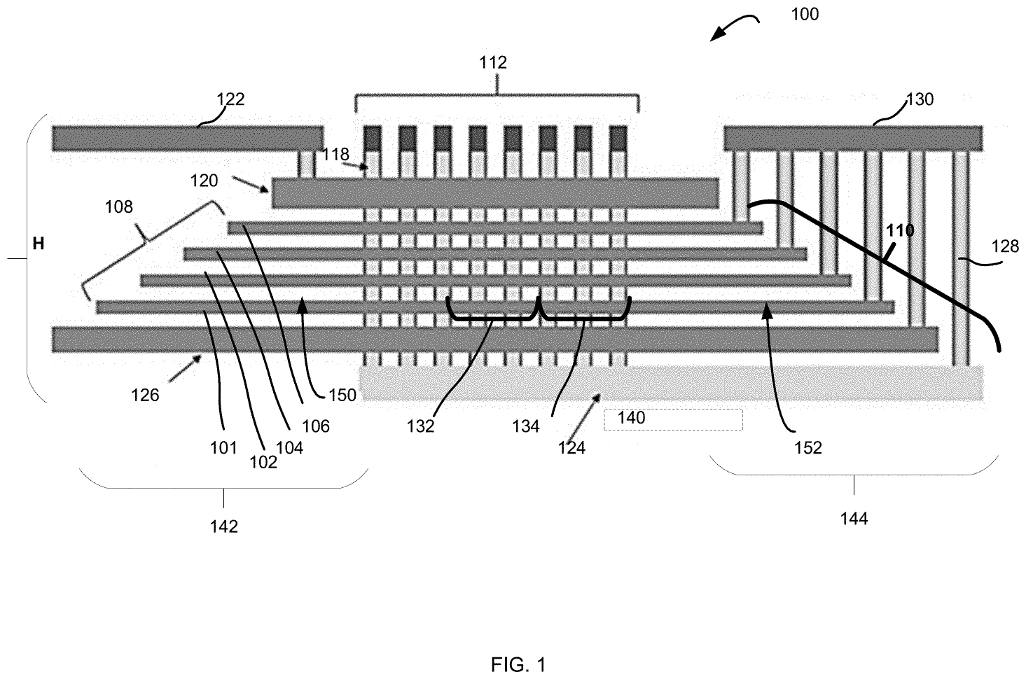

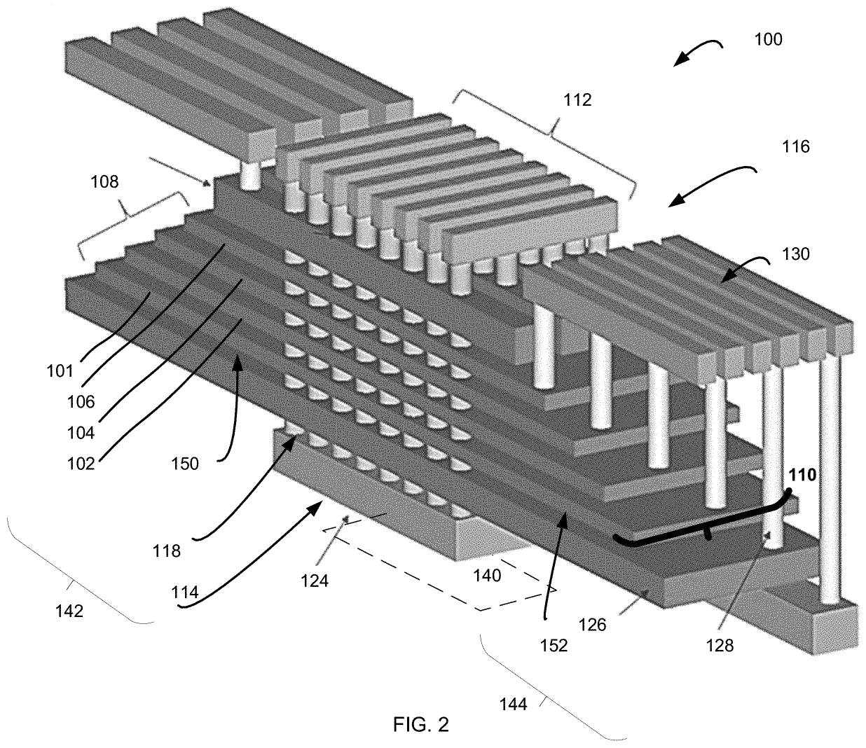

FIGS. 1-2 are example cross-section and perspective views of a memory device with a split staircase, in accordance with some embodiments. In embodiments, the memory device 100 is a non-planar device (e.g., 3D) and includes a non-volatile memory device. The memory device 100 may be a flash memory device, such as a NAND flash or a NOR flash memory device, or another kind of memory device, e.g., multilevel cell (MLC) memory device. In embodiments, the memory device 100 may be implemented as an integrated circuit (IC), e.g., in a die.

The memory cells comprising the memory device 100 include non-volatile memory cells, such that the memory cells retain information stored thereon when power is disconnected from memory device 100. In embodiments, the memory device 100 includes memory cells (not shown), which may be arranged in memory cell strings. The memory cells of a given memory cell string share a common channel region. In other words, the memory cells may be physically located in multiple levels of memory device 100, such that the memory cells in the same memory cell string may be stacked over each other in multiple levels of memory device 100, forming pillars. For simplicity, only one of the pillars is labeled (118) in FIGS. 1-2.

In embodiments, the memory device 100 includes wordlines 101, 102, 104, 106 that carry corresponding control signals and may form at least part of access lines of memory device 100. In embodiments, the memory device 100 includes data lines or bitlines 112 that carry corresponding data signals. Wordlines 101, 102, 104, 106 and bitlines 112 are shown in FIGS. 1-2 as an illustrative example only. The number of these lines may vary. In some embodiments, the bitlines and wordlines may be configured such that each of the memory elements may be disposed at an intersection of each individual bitline and wordline, in a cross-point configuration.

As shown, the wordlines 101, 102, 104, 106 may be formed in a stack of multiple wordline tiers and may form staircases 108, 110 on respective left and right sides of the memory device 100, to couple with respective pillars 118 as shown. Two staircases 108, 110 are shown in FIGS. 1-2 for ease of understanding. It should be understood that the memory device may have staircases formed on front side 114 and back side 116 of the memory device 100 (indicated in FIG. 2), in addition or in the alternative to the staircases 108, 110 formed on left and right sides 142 and 144 of the memory device 100. The staircase structure may be provided by trimming an etching on the wordlines.

In embodiments, the memory device 100 includes a bit line selector 120 with corresponding connections 122, to select bit lines. The memory device 100 further includes a common source line 124 of the memory device 100, with corresponding source line selector 126. Contacts 128 provide electrical contacts for the wordline (e.g., common gate), source line, and source line selector connections 130, as shown.

One of ordinary skill in the art may recognize that memory device 100 may include other elements, several of which are not shown in FIGS. 1-2, so as not to obscure the example embodiments described herein.

In a memory operation, for example, in a write operation, different voltages may be applied to wordlines 101, 102, 104, 106 to selectively access memory cells located in pillars (e.g., 118) in order to store information into one or more selected memory cells. Circuitry including a control circuit (not shown) may control operations of device 100 based on signals provided to the control circuit. A processing device (e.g., a processor or a memory controller, not shown) external to memory device 100 may send different commands (e.g., read, write, program verify, erase or command) to the memory device 100 via the control circuit. The control circuit may respond to commands to perform memory operations of accessing memory cells, such as a read operation to read information from memory cells and a write (e.g., programming) operation to store (e.g., program) information into memory cells. The control circuit may also perform an erase operation to clear information from some or all of memory cells.

In embodiments, the memory device 100 may comprise one or more memory blocks or tiles (each having a plurality of memory cells) disposed in a die, such as a NAND die, for example. A memory block may have different memory capacities, depending on technological demand. In operation, such as when the memory device 100 is to be accessed for data erasure, data programming, or data reading, a memory block may be selected (e.g., for erasure, programming, or reading) or deselected, in order to refrain from erasing, programming, or reading deselected blocks while the selected blocks are being erased, programmed, or read. During various operations, the control circuit may cause various memory blocks (groups of memory cells) to be selected or deselected. Accordingly, in a memory array having a plurality of memory blocks, at least one block may be selected for access (e.g., for a program mode or read mode), while other blocks may be deselected in order to refrain from access.

In order to provide a division of the memory device into memory blocks, or tiles, the memory array (e.g., wordlines 101, 102, 104, 106) may be divided into segments, e.g., segments 132 and 134 shown in FIG. 1, each segment covering a particular memory volume (e.g., 2 KB bitlines). (Such memory architecture is known as a memory tile structure.) In embodiments, two neighboring tiles may be connected through metal interconnects and have shared string drivers and other necessary circuitry, typically disposed underneath the array. Such circuitry comprises complementary metal-oxide-semiconductor (CMOS) under array circuitry (schematically shown as 140 in FIGS. 1-2). Accordingly, additional access to wordlines 101, 102, 104, 106 may be needed, in order to provide necessary electrical coupling (e.g., interconnects and interfaces) for the memory device 100.

Contacts 128 may not be able to provide such access without increasing the contact area (e.g., side 144) or height H of the device 100 (indicated in FIG. 1). Further, as the tiers may be stacked in order to increase a capacity of the memory device, the staircase trims and etches may need to be increased in order to provide space for additional interfaces with the wordlines. In other words, additional tiers provided in the device 100 may cause the amount of staircase trims and etches to increase, and eventually increase the wordline exit and a number of pads needed for electrical contact with the wordlines. The routing channel (not shown) provided to route the wordlines to respective string drivers may become congested because of increased number of tiers and may force the block height (and ultimately the device height H) to increase to fit all the wordline-propagated signals, and select gate drain and select gate source (SGD/SGS) signals.

In accordance with embodiments disclosed herein, the staircase 108 may be split in one or more locations, for example, in one or more sides 142, 144. The example split locations are indicated by numerals 150, 152 in FIGS. 1-2. An application of a hard mask to the device 100 (as described below) may allow for limiting the staircase etch to two sides (e.g., sides 142, 144, staircases 108 and 110), while refraining from the trim on the remaining sides of the device 100 (e.g., sides 114 and 116). As described below in detail, this technique provides a wordline feed through to maintain electrical continuity for all wordlines across all staircases of the memory device 100.

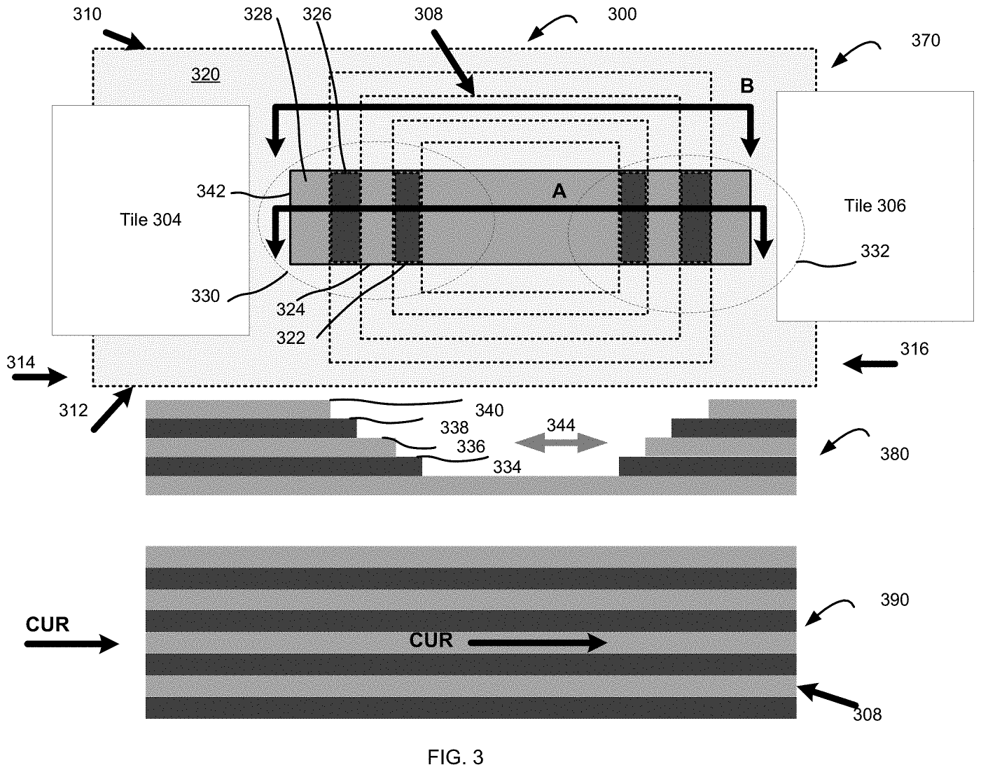

Then, using a staircase mask, the wordlines across the one side (e.g., one of 142, 144) or two sides (144 and 142) may be etched or trimmed to expose their ends for electrical coupling. The described embodiments allow for reduction (e.g., in half) of the number of staircase trims typically needed to get access to the wordlines. The described embodiments also provide for relaxing the routing channel needed. The described embodiments further provide for maintaining a desired memory block height H. The embodiments of the memory device with a split staircase are described in greater detail in reference to FIGS. 3-6.

FIG. 3 provides example views of some aspects of the memory device with a split staircase, in accordance with some embodiments. Specifically, FIG. 3 provides a top view 370 and cross-section views 380 and 390 of a portion of a memory device 300 with the split staircase. The cross-section views 380 and 390 show the schematic views of the device 300 sliced along the lines indicated by letters A and B respectively.

The memory device 300 may be provided similar to the memory device 100 of FIGS. 1-2. As shown, the memory device 300 may include multiple memory tiles 304 and 306, connected via a plurality of wordlines 308. Two tiles are shown for purposes of explanation; it should be understood that the memory device 300 (100 of FIGS. 1-2) may comprise any number of memory tiles. Typically, the tiles 304 and 306 share a string driver, so they should be connected (shorted). In conventional solutions, such connections may be provided via metal routing.

The wordlines 308 are configured in a tier fashion as described in reference to FIGS. 1-2. For purposes of explanation, four wordlines 322, 324, 326, and 328 are shown. It is understood that any number of wordlines may be stacked in a tier fashion in the memory device 300.

As shown, the memory device 300 has four sides: 310, 312, 314, and 316. Normally, the wordlines 308 would be trimmed into a staircase from all four sides. In accordance with the embodiments described herein, the sides 310 and 312 are protected from trimming by application of a hard mask 320 (indicated by the dotted line).

In embodiments, at least some of the wordlines (e.g., 322, 324, 326, and 328) are split across the tiers into portions (schematically indicated by dashed ellipsis 330 and 332). Respective ends (e.g., 334, 336, 338, 340 shown in view) of at least some (or all) of these wordlines of at least one portion 330, 332, or both portions 330 and 332, at a location of the split, may be exposed (e.g., by etching and trimming) to provide electrical coupling with other components of the memory device 300. The location of the split may be defined by application of a staircase mask 342 to the wordlines 308. Accordingly, the staircase mask, applied to the tiers of wordlines, may define location, size, and number of split and exposed wordlines in the wordline stack.

As shown in the cross-section view 380 (slice across line A), the wordlines are disconnected at the location of the split 344 defined by the staircase mask 342. Accordingly, no current can pass through the wordlines 322, 324, 326, and 328 at the location of the split 344.

In contrast, as shown in the cross-section view 390 (slice across line B), the wordlines 308 form a full-tier stack. Electrical current CUR, if applied as shown, may pass through the wordlines 308. Accordingly, the application of the staircase mask 342 provides for avoidance of conventional metal routing between the tiles 304 and 306, because current can flow directly through the wordlines 308. In other words, the wordlines in the area indicated by cross-section A provide a feed through across the device 300.

In order to provide electrical contact with every wordline in the stack, in addition to the application of a staircase mask to the wordline stack described above, an application of a chop mask may be contemplated. A chop mask is a photo and etch step that helps to expose more tiers than an application of a staircase mask would, or at least may provide for convenient exposure of the wordlines for electrical coupling.

For example, if a wordline stack comprises 32 tiers, there are different ways to provide electrical contacts for each tier. In one example, using the technique described above, the wordline stack may be staircase etched and trimmed 32 times. In another example, the stack may be staircase etched and trimmed 16 times, then half of the wordlines may be covered and a 16 tier “chop” may be performed, exposing all 32 tiers. In yet another example, a staircase etch and trim may be performed 8 times, and then two overlapping “chops” may be performed, exposing all 32 tiers. Accordingly, a number of “chop masks” used in addition to the staircase mask or masks may be optimized based on a number of wordlines in the stack, process cost, die size impact, and other factors.

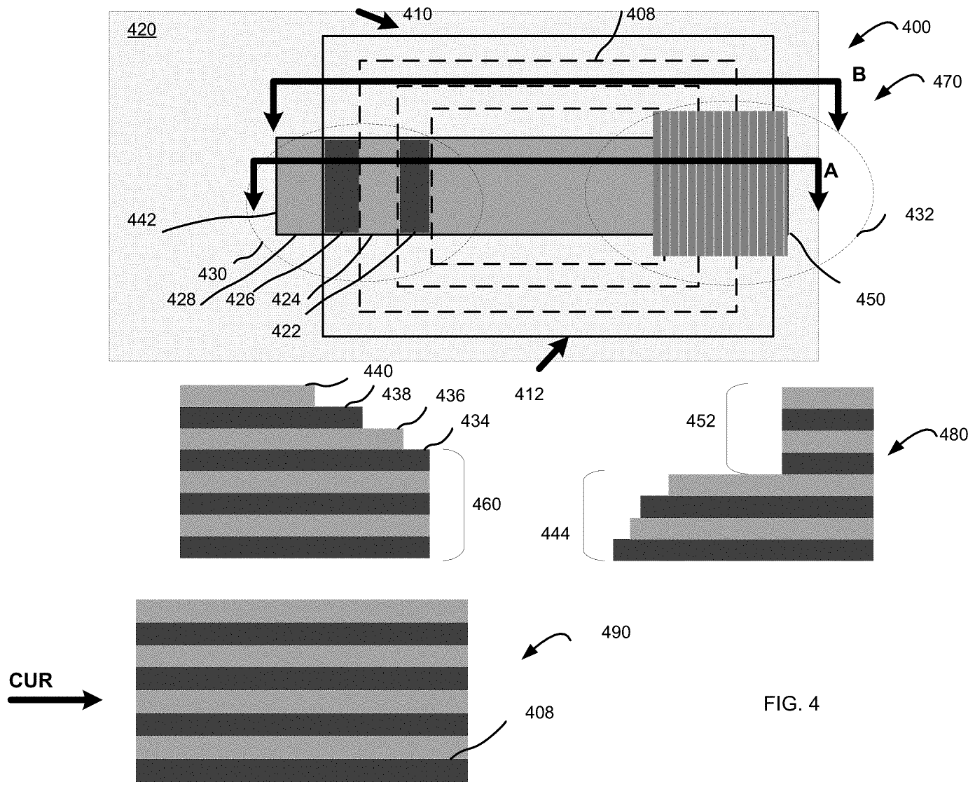

FIG. 4 provides example views of some aspects of the memory device with a split staircase and with application of a chop mask, in accordance with some embodiments. Specifically, FIG. 4 provides a top view 470 and cross-section views 480 and 490 of a portion of a memory device 400 with the split staircase. The cross-section views 480 and 490 show the schematic views of the device 400 sliced along the lines indicated by letters A and B respectively. The memory device 400 may be provided similar to the memory device 100 of FIGS. 1-2. The memory tiles are not shown for ease of explanation.

A hard mask 420 may be applied to device 400, preserving the sides 410 and 412 from trimming, similar to the embodiments described in reference to FIG. 3. A staircase mask 442 may be applied to the wordlines 408, providing for splitting the wordlines 408 across the tiers, similar to the embodiments described in reference to FIG. 3. The wordlines 422, 424, 426, 428 in the split portion 430 may be etched and trimmed to expose their respective ends 434, 436, 438, and 440 (indicated in view 480, which is a slice across line A) for electrical contacts, similar to the embodiments described in reference to FIG. 3. A few tiers below, indicated by numeral 460, may be left untrimmed.

A chop mask 450 may be applied to the wordlines 444 in split portion 432. In other words, the tiers 452 of the portion 432 that correspond to the wordlines 422, 424, 426, and 428 in the portion 430 may be chopped off, exposing the wordlines 444 corresponding to the tiers 460 in the portion 430 for trimming and exposure to electrical coupling, similar to the embodiments of FIG. 3. The wordlines 444 may be subsequently trimmed and etched, to expose their respective ends for electrical coupling.

As shown in the cross-section view 490 (slice across line B), the wordlines 408 form a full-tier stack, similar to the embodiments of FIG. 3. Electrical current CUR, if applied as shown, may pass through the wordlines 408. Similar to the embodiments of FIG. 3, the application of the staircase mask 442 provides for avoidance of conventional metal routing between the tiles (not shown), because current can flow directly through the wordlines 408. The wordlines in the area indicated by cross-section A provide a feed through across the device 400.

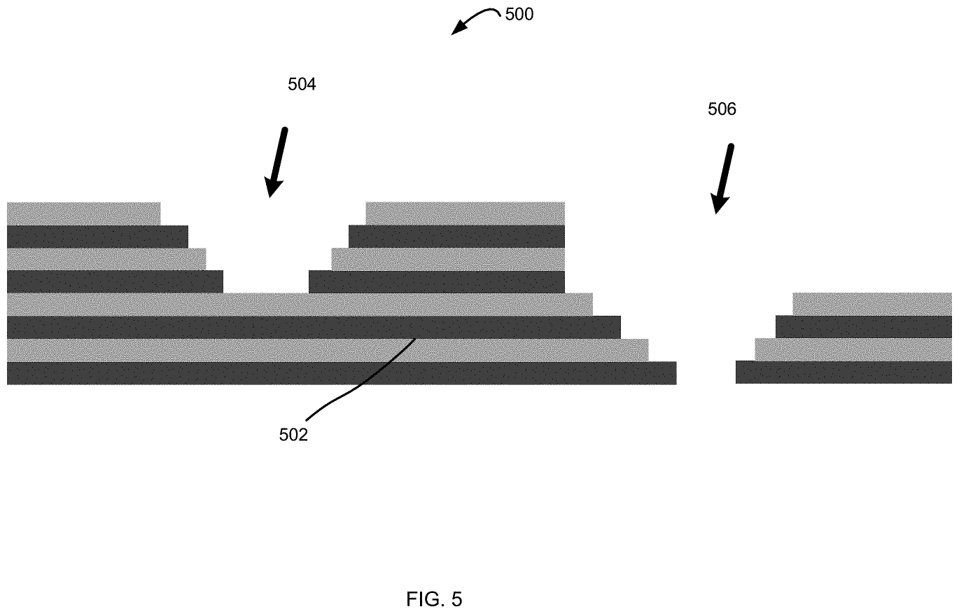

FIG. 5 is an example cross-section view of some aspects of the memory device with multiple split staircases, in accordance with some embodiments. The memory device 500 may be provided similar to the memory device 100 of FIGS. 1-2. Specifically, multiple split staircases may be provided in the memory device 500, to reduce crowding and maintain a desired memory block height. As shown, the wordline stack 502 may include a combination of split staircases, namely the staircase 504 provided by the application of a staircase mask (similar to that described in reference to FIG. 3) and the staircase 506 provided by the application of a staircase mask and a chop mask (similar to that described in reference to FIG. 4). In general, the number and shape of the staircases comprising the wordline stack may vary, depending on technological demands (desired block height, desired number of trims and etches, desired routing, and the like).

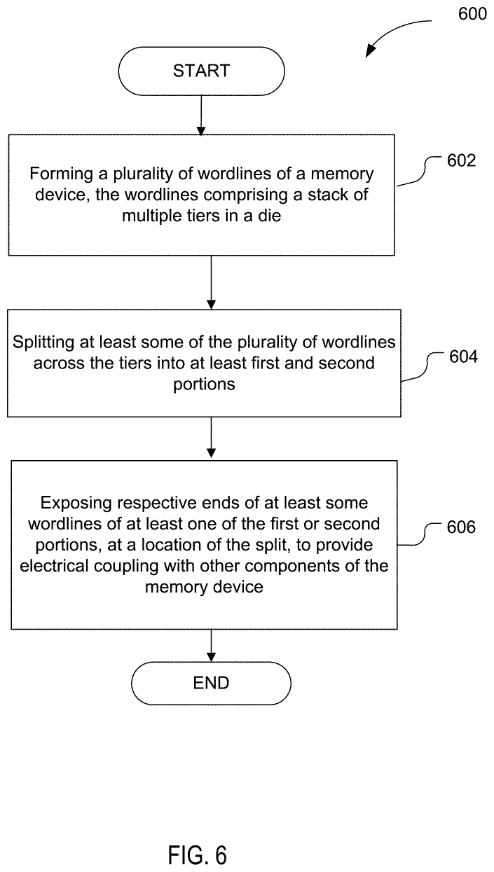

FIG. 6 is an example process flow diagram for providing a memory device with a split staircase, in accordance with some embodiments. The process 600 may comport with actions described in connection with FIGS. 1-5 in some embodiments. The process 600 may apply to formation of wordlines in a memory array in accordance with embodiments described herein.

At block 602, the process 600 includes forming a plurality of wordlines of a memory device, the wordlines comprising a stack of multiple tiers in a die. This may include applying a hard mask to the plurality of wordlines, to preserve at least two of four sides of the wordlines stack from trimming.

At block 604, the process 600 further includes splitting at least some of the plurality ofwordlines across the tiers into at least first and second portions. The splitting of wordlines across the tiers may be provided in accordance with the embodiments described in reference to FIG. 3.

At block 606, the process 600 further includes exposing respective ends of at least some wordlines of at least one of the first or second portions, at a location of the split, to provide electrical coupling with other components of the memory device.

The actions of blocks 604 and/or 606 may include applying a staircase mask to the location of the split, and trimming and etching the ends of the at least some wordlines of at least one of the first or second portions. In embodiments, the actions may further include applying a chop mask to at least another one of the first and second portions; and trimming and etching the ends of some wordlines of at least the other one of the first or second portions.

Various operations of the process 600 are described as multiple discrete operations, in a manner that is most helpful in understanding the claimed subject matter. However, the order of description should not be construed as to imply that these operations are necessarily order dependent. It will be appreciated that the sequence of operations associated with the process 600 may vary and/or include other actions in accordance with the present disclosure. As noted, the described embodiments may be implemented in a three-dimensional memory array, such as a 3D NAND memory array.

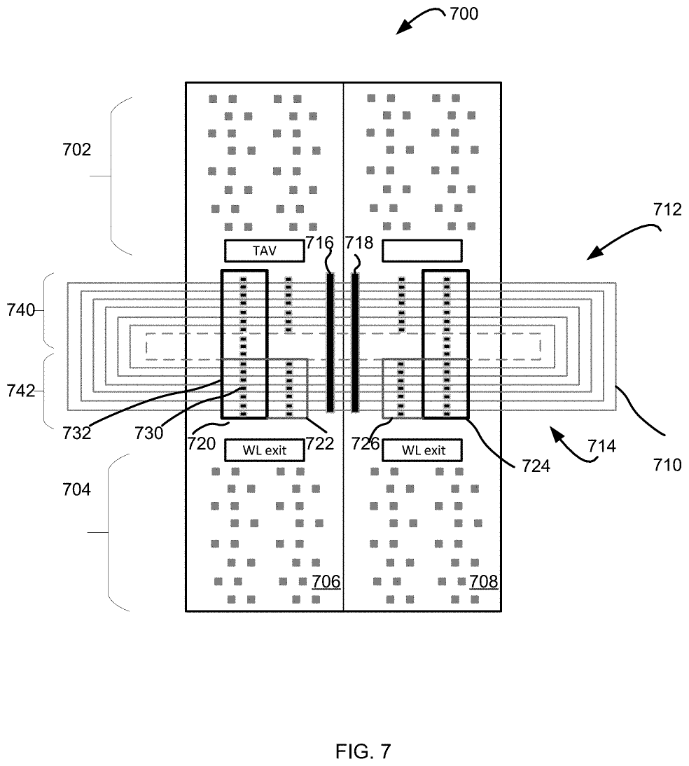

The memory arrays and methods described herein may be implemented into a system using any suitable hardware and/or software to configure as desired. FIGS. 7-11 illustrate various examples of split staircases that utilize existing non-contacted sides of staircases formed as bi-product of staircase formation to reduce complexity, routing congestion, and/or the memory block width, and improve the wordline contact quality in a 3D NAND memory array.

FIG. 7 is an example top view of some aspects of a memory device with a split staircase with application of a chop mask, in accordance with some embodiments. The example memory device 700 includes arrays 702 and 704 comprising memory blocks 706 and 708. It will be understood that the number of arrays and memory blocks in the memory device 700 may vary; the arrays 702 and 704, and blocks 706 and 708 are shown for purposes of explanation. The device 700 further includes a staircase (stadium) 710. Wordline exits and through array via (TAV) are used for routing signals to wordline drivers under the array and shown in the figure for purposes of clarity. As shown, the staircase 710 includes two sides, 712 and 714.

As discussed above, in conventional solutions, typically one side of the staircase serves for wordline contacts and another side is a dummy side of the staircase. In the described embodiments, both sides of the staircase, 712, and 714, may be used for wordline contact placement. For example, in addition to full stack preserved hard masks 716 and 718 used in conventional solutions, the staircase 710 can be chopped according to hard masks 720 and 722 (block 706), and hard masks 724 and 726 (block 708). In the described embodiments, a contact to chop space, e.g., the distance between the wordline contacts 730 that may be provided in the chopped off spaces, and the chop edges (e.g., 732), may increase, compared to conventional solutions. This may be possible because both sides 712 and 714 of the staircase 710 are used for contact provision. In other words, half 740 of the wordline contacts of the staircase 710 can be used on the side 712, and half 742 of the wordline contacts of the staircase 710 can be used on the side 714. Accordingly, in embodiments, the margin of the contact to chop space may increase to a double of the margin provided in conventional solutions. Thus, the wordline contacts 730 can safely land on respective tiers of the staircase 710, preventing potential short circuits between the tiers.

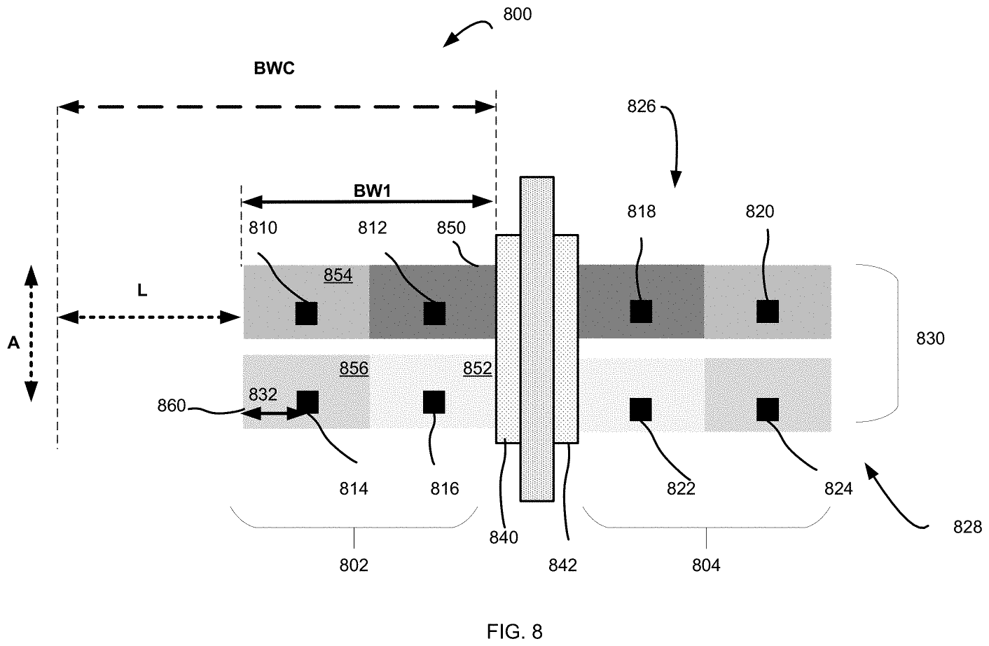

FIG. 8 is an example top view of some aspects of a memory device with a split staircase with application of a chop mask, in accordance with some embodiments. More specifically, FIG. 8 illustrates in some detail the advantages of using both sides of the staircase for placing wordline contacts, similar to the embodiments of FIG. 7. The memory device 800 includes memory blocks 802 and 804, with contact columns 810, 812, 814, and 816 disposed in block 802, and contact columns 818, 820, 822, and 824 disposed in block 804 as shown. The device 800 includes full stack preserved hard masks 840 and 842. It will be understood that the number of memory blocks in the memory device 800 may vary; blocks 802 and 804 are shown for purposes of explanation.

Similar to the embodiments of FIG. 7, both sides 826 and 828 of the staircase 830 are utilized for wordline contact placement. Also, the staircase is chopped similar to the embodiments of FIG. 7, to provide contact placement on wordlines. For example, a portion 850 of block 802 may be free of chopping. Portion 852 may be chopped according to hard mask 720 of FIG. 7. Portion 854 may be chopped according to hard mask 722 of FIG. 7. Portion 856 may be chopped according to hard masks 720 and 722 of FIG. 7. Similar arrangement applies to block 804.

In the embodiments of FIG. 8, the contact to chop space margin (distance between the contacts (e.g., 814) and the block edge (e.g., 860) indicated by arrow 832) may be kept the same as or similar to conventional solutions. Accordingly, the width BW1 of the block 802 may be reduced e.g., by a length L, compared to the width BWC of a memory block in current solutions. In embodiments, the width reduction may comprise up to 50% of BWC. In other words, instead of increasing the contact to chop space margin as described in reference to FIG. 7, the margin can be kept the same as in conventional solutions, and the block width can be reduced instead of the margin increase.

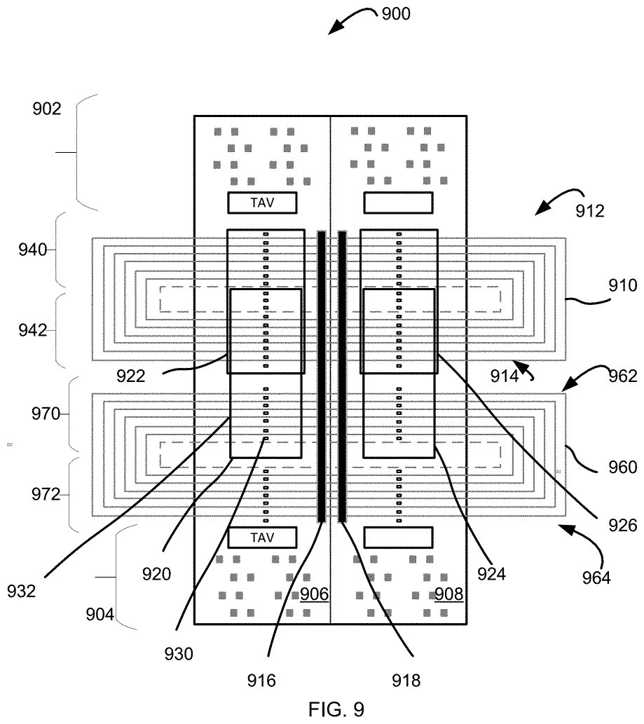

FIG. 9 is an example top view of some aspects of a memory device with multiple split staircases with application of chop masks, in accordance with some embodiments. More specifically, FIG. 9 illustrates a memory device with two staircases (stadia), in which the application of the hard masks similar to the embodiments of FIG. 7 may provide for increase of the contact to chop edge margin. It is noted that two stadia are shown for purposes of explanation; any number of stadia may be provided in the memory device, in the embodiments described herein.

As shown, the example memory device 900 includes arrays 902 and 904 comprising memory blocks 906 and 908. It will be understood that the number of arrays and memory blocks in the memory device 700 may vary; the arrays 902 and 904, and blocks 906 and 908 are shown for purposes of explanation. The device 900 further includes staircases (stadia) 910 and 960. As shown, the staircase 910 includes two sides, 912 and 914, and the staircase 960 includes two sides, 962 and 964.

In the described embodiments, both sides of the staircases 910 and 960, e.g., 912 and 914, and 962 and 964 respectively, may be used for wordline contact placement. For example, in addition to full stack preserved hard masks 916 and 918 used in conventional solutions, the staircases 910 and 960 can be chopped according to chop masks 920 and 922 (block 906), and chop masks 924 and 926 (block 908). In the described embodiments, similar to a contact to chop space, e.g., the distance between the wordline contacts 930 that may be provided in the chopped off spaces, and the chop edges (e.g., 932), may increase, compared to conventional solutions. This may be possible because both sides 912 and 914 of the staircase 910, and both sides 962 and 964 of the staircase 960 are used for contact provision. In other words, half 940 of the wordline contacts of the staircase 910 can be used on the side 912, and half 942 of the wordline contacts of the staircase 910 can be used on the side 914. Same applies to wordline contacts 970 and 972 of the staircase 960.

Accordingly, in embodiments, the margin of the contact to chop space may increase to a double of the margin provided in conventional solutions. Thus, the wordline contacts 930 can safely land on respective tiers of the staircase 910, preventing potential short circuits between the tiers. It should be noted, that instead of using hard mask 916 or 918, similar results may be achieved by shorting top ¼th the poly-oxide-poly-oxide (OPOP) stack with metal routing. For example, the wordlines that are disconnected by the stadium formation may be shorted by respective metal routing. In other words, some of the contacts (e.g. some of 940) placed on the live side 912 of the staircase 910 and some of the contacts (e.g., some of 942) placed on the “dummy” side 914 of the staircase 910 may be shorted across with a metal routing (in a bridge-like manner).

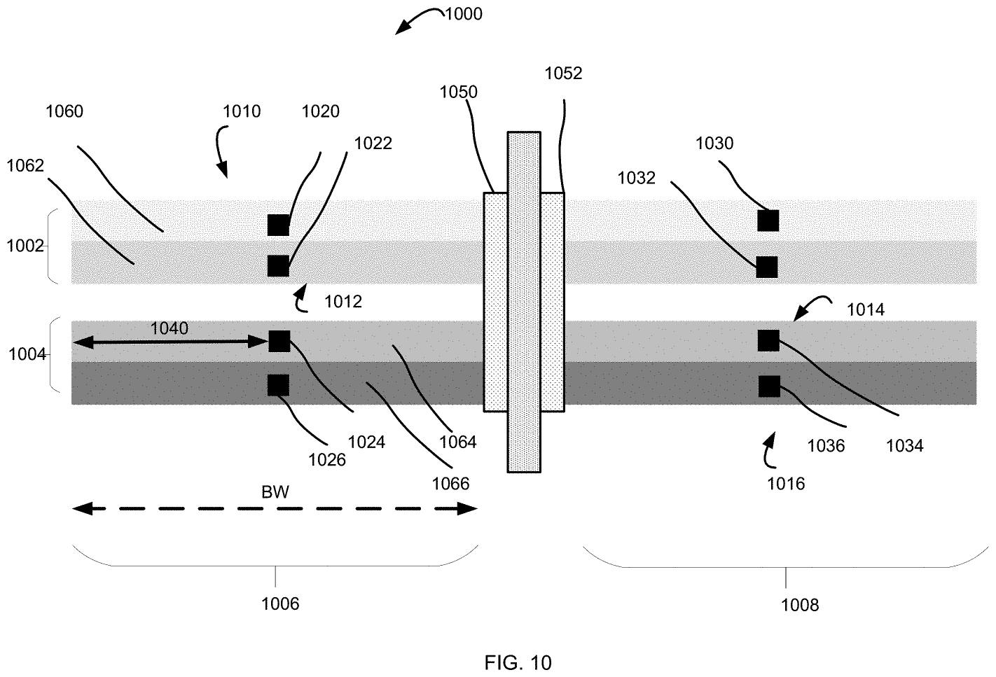

FIG. 10 is an example top view of some aspects of a memory device with multiple split staircases, in accordance with some embodiments. More specifically, FIG. 10 illustrates a memory device with two staircases (stadia), in which the application of the chop masks similar to the embodiments of FIG. 7 may provide for increase of the contact to chop edge margin. It is noted that two stadia are shown for purposes of explanation; any number of stadia may be provided in the memory device in the embodiments described herein.

As shown, the memory device 1000 includes two staircases (stadia) 1002, 1004 comprising two memory blocks 1006 and 1008. The memory device 1000 also includes contact columns 1020, 1022, 1024, and 1026 disposed in block 1006, and contact columns 1030, 1032, 1034, and 1036 disposed in block 1008 as shown. The device 1000 includes full stack preserved hard masks 1050 and 1052.

Similar to the embodiments of FIG. 7, both sides 1010 and 1012 of the staircase 1002, and both sides 1014 and 1016 of the staircase 1004 are utilized for wordline contact placement. Also, the staircases 1002 and 1004 are chopped similar to the embodiments of FIG. 7, and as further described in reference to FIG. 8, to provide contact placement on wordlines.

In the embodiments of FIG. 10, the contact to chop space margin (indicated by arrow 1040) may be increased for a given block width. In general, increase of the number of stadia in the device 1000 provides for increase (and maximization) of the margin for a given block width. This may be achieved because fewer contact columns need to be placed per stadium portion. For example, one contact column 1020 is disposed in the portion 1060 of the staircase 1002, one contact column 1022 is disposed in the portion 1062 of the staircase 1002, one contact column 1024 is placed in the portion 1064 of the staircase 1004, and one contact column 1026 is placed in the portion 1066 of the staircase 1004. Accordingly, for the given block width BW, the margin 1040 may increase compared to solutions where two contact columns are placed in the same portion of the staircase.

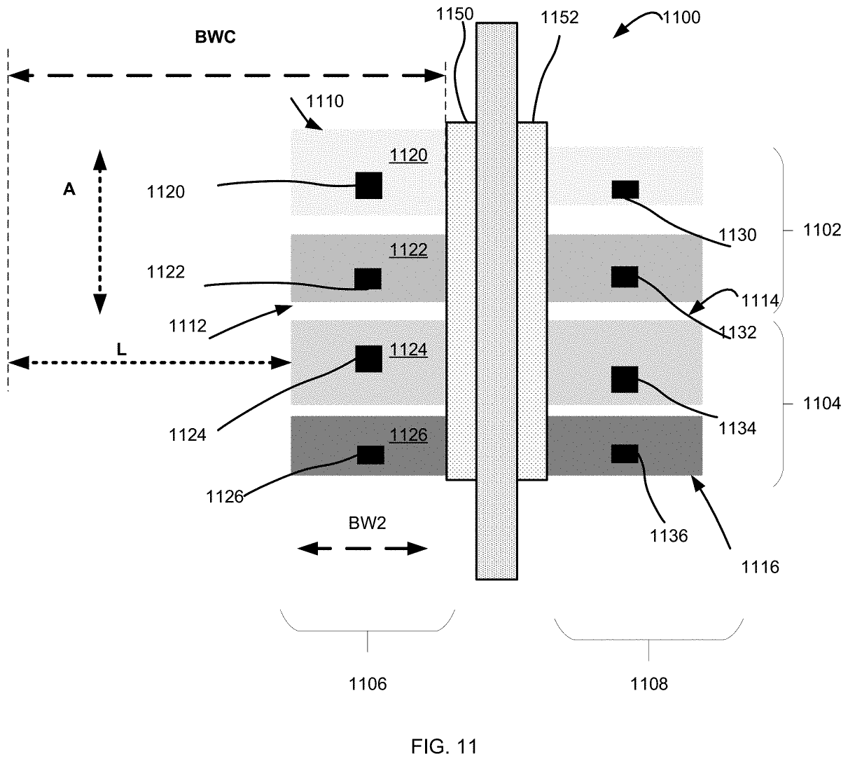

FIG. 11 is an example top view of some aspects of a memory device with multiple split staircases, in accordance with some embodiments. More specifically, FIG. 11 illustrates a memory device with two staircases (stadia), in which the application of the hard masks similar to the embodiments of FIG. 7 may provide for reduction of the memory block width. It is noted that two stadia are shown for purposes of explanation; any number of stadia may be provided in the memory device in the embodiments described herein.

As shown, the memory device 1100 includes two staircases (stadia) 1102, 1104 comprising two memory blocks 1106 and 1108. The memory device 1100 also includes contact columns 1120, 1122, 1124, and 1126 disposed in block 1106, and contact columns 1130, 1132, 1134, and 1136 disposed in block 1108 as shown. The device 1100 includes full stack preserved hard masks 1150 and 1152. Similar to the embodiments of FIG. 7, both sides 1110 and 1112 of the staircase 1102, and both sides 1114 and 1116 of the staircase 1104 are utilized for wordline contact placement. Also, the staircases 1102 and 1104 are chopped similar to the embodiments of FIG. 7, and as further described in reference to FIG. 8, to provide contact placement on wordlines.

Because two stadia are used in the device 1100, the portions 1120, 1122, 1124, and 1126 of the memory block 1106 may be disposed in one row, e.g., along the axis A, as shown. This is in contrast to the embodiments of FIG. 8, in which one stadium is provided, and the portions 850 and 852 comprise a first row (along axis A), and adjacent respective portions 854 and 856 comprise a second row adjacent to the first row. Similar arrangement applies to block 1108. Accordingly, the block width BW2 of the device 1100 may be further reduced compared to the block width BW1 of the device 800 of FIG. 8. For example, the block width BW2 of the device 1100 may be reduced to 50% of the width BW1 of the device 800, and reduced to 75% of the conventional block width BWC shown in FIGS. 8 and 11. In other words, the length L comprising the difference between BW2 and BWC may equal 75% of the BWC. This reduction may be based on the assumption that the conventional margins are kept the same.

The embodiments described in reference to FIGS. 7-11 are generally based on the use of the existing non-contacted side of the staircase that is formed as a bi-product of staircase formation in floating gate (FG) designs. The use of dummy side of the staircase formation for electrical purposes can provide higher performance if a memory device, especially during programming. The application of the hard mask provides for making the dummy side of the staircase electrically live. The wordline contacts may then be placed on both sides of the staircase to improve contact to chop margin and/or reduce block width in the FG NAND memory device.

Accordingly, the application of the hard mask to the staircase as described herein provides for connectivity on the non-contacted side of the staircase. This helps to improve the contact to chop edge margin, reduce the block width, reduce the routing congestion, and any combination of the above to balance for market needs and/or reducing the process complexity. The application of the hard mask helps to connect the poly-oxide-poly-oxide (OPOP) across to the non-contacted side of the staircase. This helps to reduce the routing congestion. As noted above, in the alternative, existing layers of metal may be used to short the ¼th OPOP stack across the staircase, in order to provide contacts on the non-contacted side of the staircase without application of the hard mask, in order to save costs.

The embodiments described in reference to FIGS. 7-11 provide for the following advantages. For example, the block width and the contact to chop edge margin of the memory device can be adjusted correspondingly in order to optimize the memory device capability and the manufacturing and development process. Further, the increase of the staircase contact to chop margins can lead to reduction of the reticle turns for chop masks. As known, reticle is a stencil to print various layers to eventually form a circuit. There is significant cost associated with each mask production to produce wafers of memory devices. A few reticles are typically used to dial in the margin to get better yields. Using the embodiments described herein, the staircase contact to chop margins can be increased and thus the cost of reticles can be reduced, speeding up of the process development, and better yields in production of memory devices.

Further, the reduction of the block size according to the embodiments described herein reduces the wordline capacitance (C) that needs to be driven by the string driver. Resistance (R) may increase with smaller block size, but if the resulting R*C is lower, better performance in terms of lower time to program a memory cell (TPROG) may be achieved.

Also, for memory technology, it is desirable to be able to address each memory bit individually to read, write or erase. As the block size may be reduced according to the embodiments described herein, the goal of addressing each memory bit becomes more attainable. Furthermore, for reliability and defect probability purposes, it is desirable to operate with smaller memory blocks because a lesser number of bits may be lost when a memory block fails. Further, fewer contacts along the width of the block can open up some space for the metal routing to reduce the congestion.

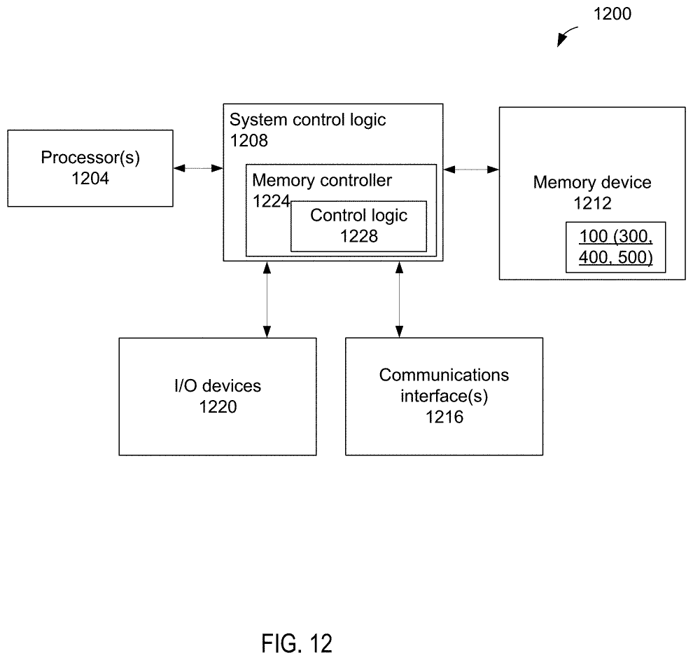

FIG. 12 schematically illustrates an example computing device including a memory device with a split staircase, in accordance with some embodiments. The computing device 1200 includes system control logic 1208 coupled to one or more processor(s) 1204; a memory device 1212 having a memory device 100 (300, 400, or 500) described in reference to FIGS. 3-5; one or more communications interface(s) 1216; and input/output (I/O) devices 1220.

The memory device 1212 may be a non-volatile computer storage chip (e.g., provided on the die) that may include the memory device 100 (300, 400, or 500) of FIGS. 1-5. In embodiments, the memory device 1212 comprises a package, such as an IC assembly having the memory device 100 (300, 400, or 500) disposed therein, driver circuitry (e.g., drivers), input/output connections to electrically couple the memory device 1212 with other components of the computing device 1200, etc. The memory device 1212 may be configured to be removably or permanently coupled with the computing device 1200.

Communications interface(s) 1216 may provide an interface for computing device 1200 to communicate over one or more network(s) and/or with any other suitable device. Communications interface(s) 1216 may include any suitable hardware and/or firmware. Communications interface(s) 1216 for one embodiment may include, for example, a network adapter, a wireless network adapter, a telephone modem, and/or a wireless modem. For wireless communications, communications interface(s) 1216 for one embodiment may use one or more antennas to communicatively couple the computing device 1200 with a wireless network.

For one embodiment, at least one of the processor(s) 1204 may be packaged together with logic for one or more controller(s) of system control logic 1208. For one embodiment, at least one of the processor(s) 1204 may be packaged together with logic for one or more controllers of system control logic 1208 to form a System in Package (SiP). For one embodiment, at least one of the processor(s) 1204 may be integrated on the same die with logic for one or more controller(s) of system control logic 1208. For one embodiment, at least one of the processor(s) 1204 may be integrated on the same die with logic for one or more controller(s) of system control logic 1208 to form a System on Chip (SoC).

System control logic 1208 for one embodiment may include any suitable interface controllers to provide for any suitable interface to at least one of the processor(s) 1204 and/or to any suitable device or component in communication with system control logic 1208. The system control logic 1208 may move data into and/or out of the various components of the computing device 1200.

System control logic 1208 for one embodiment may include a memory controller 1224 to provide an interface to the memory device 1212 to control various memory access operations. The memory controller 1224 may include control logic 1228 that may be specifically configured to control access of the memory device 1212.

In various embodiments, the I/O devices 1220 may include user interfaces designed to enable user interaction with the computing device 1200, peripheral component interfaces designed to enable peripheral component interaction with the computing device 1200, and/or sensors designed to determine environmental conditions and/or location information related to the computing device 1200. In various embodiments, the user interfaces could include, but are not limited to, a display, e.g., a liquid crystal display, a touch screen display, etc., a speaker, a microphone, one or more digital cameras to capture pictures and/or video, a flashlight (e.g., a light emitting diode flash), and a keyboard. In various embodiments, the peripheral component interfaces may include, but are not limited to, a non-volatile memory port, an audio jack, and a power supply interface. In various embodiments, the sensors may include, but are not limited to, a gyro sensor, an accelerometer, a proximity sensor, an ambient light sensor, and a positioning unit. The positioning unit may additionally/alternatively be part of, or interact with, the communication interface(s) 1216 to communicate with components of a positioning network, e.g., a global positioning system (GPS) satellite.

In various embodiments, the computing device 1200 may be a mobile computing device such as, but not limited to, a laptop computing device, a tablet computing device, a netbook, a smartphone, etc.; a desktop computing device; a workstation; a server; etc. The computing device 1200 may have more or fewer components, and/or different architectures. In further implementations, the computing device 1200 may be any other electronic device that processes data.

According to various embodiments, the present disclosure describes a number of examples.

Example 1 is an apparatus, comprising: one or more pillars disposed in a die; and a plurality of wordlines formed in a stack of multiple tiers and coupled with the one or more pillars, wherein at least some of the plurality of wordlines are split across the tiers into at least first and second portions, wherein respective ends of at least some wordlines of at least one of the first or second portions, at a location of the split, are exposed to provide electrical coupling with other components of the apparatus.

Example 2 includes the subject matter of Example 1, wherein each of the one or more pillars comprise one or more memory cells formed in a stacked fashion.

Example 3 includes the subject matter of Example 1, wherein the at least some of the plurality of wordlines are split across the tiers by application of a staircase mask to the location of the split, wherein the respective ends of at least some wordlines of at least one of the first or second portions are exposed by trimming in accordance with the applied staircase mask.

Example 4 includes the subject matter of Example 1, wherein the plurality of wordlines comprise four sides, wherein at least two of the four sides are free from trimming by application of a hard mask to the plurality of wordlines.

Example 5 includes the subject matter of Example 4, wherein the apparatus comprises at least first and second memory tiles, wherein the first and second memory tiles are connected via wordlines located at the two of four sides of the plurality of wordlines that are free from trimming.

Example 6 includes the subject matter of Example 5, wherein the connection via the wordlines comprises a wordline feed through, to maintain electrical continuity across the first and second memory tiles.

Example 7 includes the subject matter of Example 1, wherein the apparatus comprises one or more memory blocks with a determined height.

Example 8 includes the subject matter of Example 1, wherein the apparatus comprises a three-dimensional (3D) NAND memory array.

Example 9 includes the subject matter of any of Examples 1 to 8, wherein the apparatus comprises an integrated circuit.

Example 10 is a computing system, comprising: a processor; and a memory coupled with the processor, wherein the memory includes: one or more pillars disposed in a die; and a plurality of wordlines formed in a stack of multiple tiers and coupled with the one or more pillars, wherein at least some of the plurality of wordlines are split across the tiers into at least first and second portions, wherein respective ends of at least some wordlines of at least one of the first or second portions, at a location of the split, are exposed to provide electrical coupling with other components of the computing system.

Example 11 includes the subject matter of Example 10, wherein the plurality of wordlines comprise four sides, wherein at least two of the four sides are free from trimming by application of a hard mask to the plurality of wordlines.

Example 12 includes the subject matter of Example 10, wherein the at least some of the plurality of wordlines are split across the tiers by application of a staircase mask to the location of the split, wherein the respective ends of at least some wordlines of at least one of the first or second portions are exposed by trimming in accordance with the applied staircase mask.

Example 13 includes the subject matter of Example 10, wherein each of the one or more pillars comprise one or more memory cells formed in a stacked fashion.

Example 14 includes the subject matter of Example 11, wherein the memory includes at least first and second memory tiles, wherein the first and second memory tiles are connected via wordlines located at the two of four sides of the plurality of wordlines that are free from trimming.

Example 15 includes the subject matter of any of Examples 10 to 14, wherein the computing system is a mobile computing device.

Example 16 is a method, comprising: forming a plurality of wordlines of a memory device, the wordlines comprising a stack of multiple tiers in a die; splitting at least some of the plurality of wordlines across the tiers into at least first and second portions; and exposing respective ends of at least some wordlines of at least one of the first or second portions, at a location of the split, to provide electrical coupling with other components of the memory device.

Example 17 includes the subject matter of Example 16, further comprising coupling the wordlines with one or more pillars disposed in the die, wherein each of the one or more pillars comprise one or more memory cells formed in a stacked fashion.

Example 18 includes the subject matter of Example 16, wherein the plurality of wordlines comprise four sides, wherein forming the plurality of wordlines includes applying a hard mask to the plurality of wordlines, to preserve at least two of the four sides from trimming.

Example 19 includes the subject matter of any of Examples 16 to 18, wherein exposing the respective ends of at least some wordlines includes: applying a staircase mask to the location of the split; and trimming and etching the ends of the at least some wordlines of at least one of the first or second portions.

Example 20 includes the subject matter of Example 19, wherein exposing the respective ends of at least some wordlines further includes: applying a chop mask to at least another one of the first and second portions; and trimming and etching the ends of some wordlines of the other one of the first or second portions.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to specific implementations disclosed in the specification and the claims. Rather, the scope is to be determined entirely by the following claims, which are to be construed in accordance with established doctrines of claim interpretation.

1. An apparatus, comprising:
one or more pillars disposed in a die; and
a plurality of wordlines formed in a stack of multiple tiers and coupled with the one or more pillars,
wherein at least some of the plurality of wordlines are split across the tiers into at least first and second portions, wherein respective ends of at least some wordlines of at least one of the first or second portions, at a location of the split, are exposed to provide electrical coupling with other components of the apparatus.

2. The apparatus of claim 1, wherein each of the one or more pillars comprise one or more memory cells formed in a stacked fashion.

3. The apparatus of claim 1, wherein the at least some of the plurality of wordlines are split across the tiers by application of a staircase mask to the location of the split, wherein the respective ends of at least some wordlines of at least one of the first or second portions are exposed by trimming in accordance with the applied staircase mask.

4. The apparatus of claim 1, wherein the plurality of wordlines comprise four sides, wherein at least two of the four sides are free from trimming by application of a hard mask to the plurality of wordlines.

5. The apparatus of claim 4, wherein the apparatus comprises at least first and second memory tiles, wherein the first and second memory tiles are connected via wordlines located at the two of four sides of the plurality of wordlines that are free from trimming.

6. The apparatus of claim 5, wherein the connection via the wordlines comprises a wordline feed through, to maintain electrical continuity across the first and second memory tiles.

7. The apparatus of claim 1, wherein the apparatus comprises one or more memory blocks with a determined height.

8. The apparatus of claim 1, wherein the apparatus comprises a three-dimensional (3D) NAND memory array.

9. The apparatus of claim 1, wherein the apparatus comprises an integrated circuit.

10. A computing system, comprising:
a processor; and
a memory coupled with the processor, wherein the memory includes:
one or more pillars disposed in a die; and a plurality of wordlines formed in a stack of multiple tiers and coupled with the one or more pillars, wherein at least some of the plurality of wordlines are split across the tiers into at least first and second portions, wherein respective ends of at least some wordlines of at least one of the first or second portions, at a location of the split, are exposed to provide electrical coupling with other components of the computing system.

11. The computing system of claim 10, wherein the plurality of wordlines comprise four sides, wherein at least two of the four sides are free from trimming by application of a hard mask to the plurality of wordlines.

12. The computing system of claim 10, wherein the at least some of the plurality of wordlines are split across the tiers by application of a staircase mask to the location of the split, wherein the respective ends of at least some wordlines of at least one of the first or second portions are exposed by trimming in accordance with the applied staircase mask.

13. The computing system of claim 10, wherein each of the one or more pillars comprise one or more memory cells formed in a stacked fashion.

14. The computing system of claim 11, wherein the memory includes at least first and second memory tiles, wherein the first and second memory tiles are connected via wordlines located at the two of four sides of the plurality of wordlines that are free from trimming.

15. The computing system of claim 10, wherein the computing system is a mobile computing device.

16. A method, comprising:
forming a plurality of wordlines of a memory device, the wordlines comprising a stack of multiple tiers in a die;
splitting at least some of the plurality of wordlines across the tiers into at least first and second portions; and
exposing respective ends of at least some wordlines of at least one of the first or second portions, at a location of the split, to provide electrical coupling with other components of the memory device.

17. The method of claim 16, further comprising coupling the wordlines with one or more pillars disposed in the die, wherein each of the one or more pillars comprise one or more memory cells formed in a stacked fashion.

18. The method of claim 16, wherein the plurality of wordlines comprise four sides, wherein forming the plurality of wordlines includes applying a hard mask to the plurality of wordlines, to preserve at least two of the four sides from trimming.

19. The method of claim 16, wherein exposing the respective ends of at least some wordlines includes:
applying a staircase mask to the location of the split; and
trimming and etching the ends of the at least some wordlines of at least one of the first or second portions.

20. The method of claim 19, wherein exposing the respective ends of at least some wordlines further includes:
applying a chop mask to at least another one of the first and second portions; and
trimming and etching the ends of some wordlines of the other one of the first or second portions.
